(19) United States
(12) Patent Application Publication
(10) Pub. No.: US 2026/0253829 A1
(43) Pub. Date: Aug. 27, 2026

(54) PROTECTING DEVICE

(71) Applicant: DEXERIALS CORPORATION, Tochigi (JP)

(72) Inventor: Chisato KOMORI, Tochigi (JP)

(73) Assignee: DEXERIALS CORPORATION, Tochigi (JP)

(21) Appl. No.: 18/877,869

(22) PCT Filed: Jun. 28, 2023
(86) PCT No.: PCT/JP2023/024087

§ 371 Date: Dec. 20, 2024

(30) Foreign Application Priority Data
Jul. 20, 2022 (JP) 2022-115341

(51) Int. Cl. H01H 85/02; H01H 37/76; H01H 85/06; H01M 50/583; H10W 20/49

(52) U.S. Cl. CPC H01H 85/0241; H01H 37/761; H01H 85/06; H01M 50/583; H10W 20/493; H01H 2085/0275; H01H 2085/0283

(57) ABSTRACT

Provided is a protecting device capable of avoiding an environmental burden, preventing an effect of reflow mounting on the rapid blowout property of a fuse element, and also reducing the cost. A protecting device 1 includes an insulating substrate 2, a first electrode 4 and a second electrode 5 provided on the insulating substrate 2, a fuse element 7 disposed on surfaces of the first electrode 4 and the second electrode 5 to electrically connects the first electrode 4 and the second electrode 5 to the fuse element 7, and a connecting conductor 8 connecting the first electrode 4 and the second electrode 5 to the fuse element 7, wherein the fuse element 7 is made of a lead-free conductor and has a liquidus point higher than the reflow heating temperature, and the connecting conductor 8 has a solidus point lower than the liquidus point of the fuse element 7 and below the reflow heating temperature.

### CROSS REFERENCE TO PRIOR APPLICATION

This application is a National Stage Patent Application of PCT International Patent Application No. PCT/JP2023/024087 (filed on Jun. 28, 2023) under 35 U.S.C. § 371, which claims priority to Japanese Patent Application No. 2022-115341 (filed on July 20, 2022), which are all hereby incorporated by reference in their entirety.

### TECHNICAL FIELD The present technology relates to a protecting device mounted on a current path that blows a fuse element and interrupts the current path in the event of an abnormality.

### BACKGROUND ART

Lithium-ion secondary batteries (LiBs) are high power, high energy density batteries that are being used in a variety of applications as battery performance improves. However, LiBs have a risk of overheating and causing smoke and fire if they are overcharged due to a fault in the IC or FET that controls charging and discharging; therefore a protecting device with a heat generator is employed as a secondary protection measure. With the expansion of LiB-equipped applications, the production volume of LiBs is increasing and the demand for protective devices to protect LiBs is growing.

Since many of the components used to control LiBs, including the ICs and FETs mentioned above, are surface mount compatible, the protection devices must also be surface mount compatible. In addition, in order to safely complete the fuse element blowing operation with the built-in heat generator, the melting point of the fuse element should be as low as possible, and it is ideally a melting point (around 280° C. to 300° C.) that can just barely withstand the reflow temperature (260° C.).

To meet this requirement, fuse elements are generally made of alloys with a high lead content from the cost perspective. However, new fuse elements with new structures that do not contain lead have been proposed in response to the growing demand for reduced environmental impact.

FIGS. 10A to 10C show an example of a protecting device, in which FIG. 10A is a plan view with the cover member omitted, FIG. 10B is a cross-sectional view, and FIG. 10C is a bottom view. The protecting device 100 shown in FIG. 10 includes an insulating substrate 101, first and second electrodes 102, 103 formed on the front surface of the insulating substrate 101, a heat generator 104 formed on the front surface of the insulating substrate 101, an insulating layer 105 covering the heat generator 104, a heat-generator lead-out electrode 106 laminated on the insulating layer 105 and connected to the heat generator 104, and a fuse element 107, which is a meltable conductor, mounted over the first electrode 102, the heat-generator lead-out electrode 106, and the second electrode 103 via a connection material 110.

The same type of material as the fuse element 107 can be used as the connection material 110, e.g., various tin-based solder pastes such as Pb—Sn, Au—Sn, and Sn—Cu—Ag solder pastes can be used.

The first and second electrodes 102, 103 are terminals to be connected to a current path of the external circuit to which the protecting device 100 is connected and are connected via castellation to the first and second external connection electrodes 102a, 103a formed on the back surface of the insulating substrate 101, respectively. The fuse element 107 is incorporated into part of the current path formed on the external circuit board by connecting the first and second external connection electrodes 102a, 103a to the connection electrodes formed on the external circuit board on which the protecting device 100 is mounted.

The heat generator 104 is an electrically conductive member having a relatively high resistance value and generating heat when energized, and is made of, e.g., nichrome, W, Mo, Ru, or a material containing these materials. The heat generator 104 is connected to a heat-generator electrode 108 formed on the front surface of the insulating substrate 101. The heat-generator electrode 108 is connected via castellation to a third external connection electrode 108a formed on the back surface of the insulating substrate 101. The heat generator 104 is connected to an external power source on the external circuit by connecting the third external connection electrode 108a to the connection electrode formed on the external circuit board on which the protecting device 100 is mounted. The energizing state of the heat generator 104 is controlled at all times by a switch element or the like, which is not shown in the figure.

The heat generator 104 is covered by an insulating layer 105 made of a glass layer or the like and the heat-generator lead-out electrode 106 is formed on the insulating layer 105, so that the heat generator 104 overlaps the heat-generator lead-out electrode 106 via the insulating layer 105. In addition, the fuse element 107 connected across the first and second electrodes 102, 103 is connected on the heat-generator lead-out electrode 106 via the connection material 110.

As a result, the heat generator 104 overlaps and is thermally connected with the fuse element 107, and the protecting device 100 can melt the fuse element 107 when the heat generator 104 is energized to generate heat.

The fuse element 107 is connected from the first electrode 102 through the heat-generator lead-out electrode 106 to the second electrode 103, thereby forming part of the current path of the external circuit in which the protecting device 100 is incorporated. The fuse element 107 melts due to self-heating (Joule heat) when a current exceeding the rated value is applied or melts due to the heat generated by the heat generator 104, thereby interrupting the connection between the first and second electrodes 102, 103.

### CITATION LIST

### Patent Literature

Patent Document 1: JP 2790433 B
Patent Document 2: JP 2015-035281 A

### SUMMARY OF INVENTION

### Technical Problem

The fuse element 107 can be formed by a high-melting-point solder containing 85 wt % or more lead, such as Pb—Sn, for example. However, as mentioned above, with the increasing demand for environmental load reduction, the use of lead-containing solders is only allowed to a limited extent under the RoHS Directive or the like and the demand for Pb-free solder is expected to increase in the future.

When lead-free solder is used as the fuse element 107, its melting point is higher than that of lead-containing solder, making it difficult to melt quickly with the heat generated by the heat generator 104. The use of high-melting-point solder with more than 80 wt % gold, such as Au—Sn, as fuse element 107 has the advantage of not containing environmentally hazardous substances but also results in higher costs.

The problem of both environmental impact and cost can be solved by coating a low-melting-point (melting point: about 220° C.) tin-based metal 107a such as Sn—Ag—Cu with a high-melting-point (melting point: 600° C. or higher) metal 107b such as Ag as the fuse element 107. However, as shown in FIG. 11, if the cross-sectional shape of the fuse element 107 changes due to the flow and uneven distribution of the low-melting-point metal 107a melted at the heating temperature (about 260° C.) during the surface mounting process, there is a concern that the rapid blowout property may be impaired due to variations in resistance values. Although the unevenness of the low-melting-point metal 107a can be suppressed by thickening the high-melting-point metal 107b that coats the low-melting-point metal 107a, there is a risk that the blowout time will be prolonged by the heat generated by the heat generator 104 or that the heat generator 104 will be damaged before the fuse element 107 melts. As a countermeasure against deformation of the fuse element 107, it has been proposed to form a pillar of high-melting-point metal 107b inside the fuse element 107, but this would increase the manufacturing cost.

Therefore, an object of the present technology is to provide a protecting device that can avoid environmental load, prevent the effect of reflow mounting on the rapid blowout property of the fuse element, and also reduce the cost.

### Solution to Problem

In order to solve the above-described problems, a protecting device of the present technology includes: an insulating substrate; a first electrode and a second electrode provided on the insulating substrate; a fuse element disposed on surfaces of the first electrode and the second electrode to electrically connect the first electrode and the second electrode; and a connecting conductor that connects the first and second electrodes to the fuse element, wherein the fuse element is made of a lead-free conductor and has a liquidus point higher than the reflow heating temperature, and the connecting conductor has a liquidus point lower than the liquidus point of the fuse element and has a solidus point lower than the reflow heating temperature.

### Advantageous Effects of Invention

The present technology can avoid environmental load, prevent changes in electrical properties during reflow mounting, and also reduce the cost.

### BRIEF DESCRIPTION OF DRAWINGS

FIGS. 1A-1C show a protecting device according to the present technology in which FIG. 1A is a plan view with the cover member omitted, FIG. 1B is a cross-sectional view, and FIG. 1C is a bottom view.

FIG. 2 is a plan view illustrating the fuse element in a melted state.

FIG. 3 is a plan view illustrating a protecting device with a fuse element mounted between the first electrode and the heat-generator lead-out electrode and between the heat-generator lead-out electrode and the second electrode, respectively, with the cover member omitted.

FIG. 4 is a circuit diagram of a battery pack in which the protecting device according to the present technology is mounted.

FIG. 5 is a circuit diagram of a protecting device according to the present technology.

FIGS. 6A-6C show a modification of a protecting device according to the present technology, in which FIG. 6A is a plan view with the cover member omitted, FIG. 6B is a cross-sectional view, and FIG. 6C is a bottom view.

FIGS. 7A-7C show a modification of a protecting device according to the present technology, in which FIG. 7A is a plan view with the cover member omitted, FIG. 7B is a cross-sectional view, and FIG. 7C is a bottom view.

FIG. 8 is a circuit diagram of a protecting device of the modification.

FIGS. 9A-9C show a modification of a protecting device according to the present technology, in which FIG. 9A is a plan view with the cover member omitted, FIG. 9B is a cross-sectional view, and FIG. 9C is a bottom view.

FIGS. 10A-10C show an example of a protecting device, in which FIG. 10A is a plan view with the cover member omitted, FIG. 10B is a cross-sectional view, and FIG. 10C is a bottom view.

FIG. 11 shows a cross-sectional view of a fuse element in which the cross-sectional shape of the fuse element has changed due to the melted low-melting-point metal flowing and unevenly distributed at the heating temperature (around 260° C.) in the surface mounting process.

### DESCRIPTION OF EMBODIMENTS

Embodiments of a protecting device according to the present technology will now be more particularly described with reference to the accompanying drawings. It should be noted that the present technology is not limited to the embodiments described below and various modifications can be added to the embodiment without departing from the scope of the present technology. The features shown in the drawings are illustrated schematically and are not intended to be drawn to scale. Actual dimensions should be determined in consideration of the following description. Moreover, dimensional relations and proportions may be different among the drawings in some parts.

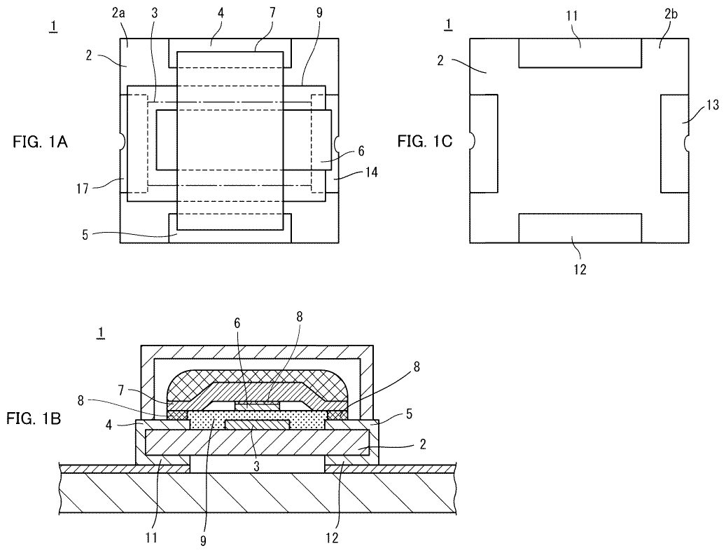

As shown in FIG. 1A to 1C, the protecting device 1 according to the present technology includes an insulating substrate 2, a first electrode 4 and a second electrode 5 provided on the insulating substrate 2, a fuse element 7 which is a meltable conductor disposed on a surface of the first electrode 4 and the second electrode 5 to electrically connect the first electrode 4 and the second electrode 5, and a connecting conductor 8 that connects the first electrode 4 and the second electrode 5 to the fuse element 7.

The fuse element 7 is made of an alloy having a material composition which does not contain lead and has a liquidus point higher than the reflow heating temperature. In other words, the fuse element 7 does not melt at the reflow heating temperature. Therefore, the fuse element 7 can be reflow-mounted on the first and second electrodes 4, 5 without melting during the reflow process. Since the fuse element 7 does not melt in the reflow process, the protecting device 1 can be mounted on an external circuit board by reflow.

The connecting conductor 8 has a liquidus point lower than the liquidus point of the fuse element 7 and has a solidus point lower than the reflow heating temperature. In other words, the connecting conductor 8 has a lower melting point than the fuse element 7. As a result, the connecting conductor 8 is provided for connection between the fuse element 7 and the first and second electrodes 4, 5 in an at least partially melted state at the reflow heating temperature. Since the connecting conductor 8 is more melted than the fuse element 7, the connecting conductor 8 is wetly spread over the first and second electrodes 4, 5 and fills the space between the fuse element 7 and the first and second electrodes 4, 5 to electrically and mechanically connect them.

The liquidus point of the connecting conductor 8 may be higher than the reflow heating temperature, but lower is preferred. This is because it is preferable to provide a good electrical and mechanical connection between the fuse element 7 and the first and second electrodes 4, 5 in a completely melted state.

Thus, by using as the fuse element 7 an alloy having a material composition which does not use lead and has a liquidus point higher than the reflow heating temperature, the protecting device 1 has an excellent rapid blowout property while reducing the environmental burden. In addition, it is possible to reduce the environmental impact while maintaining the rapid blowout property without using expensive metals such as gold as the fuse element 7, thus reducing the cost.

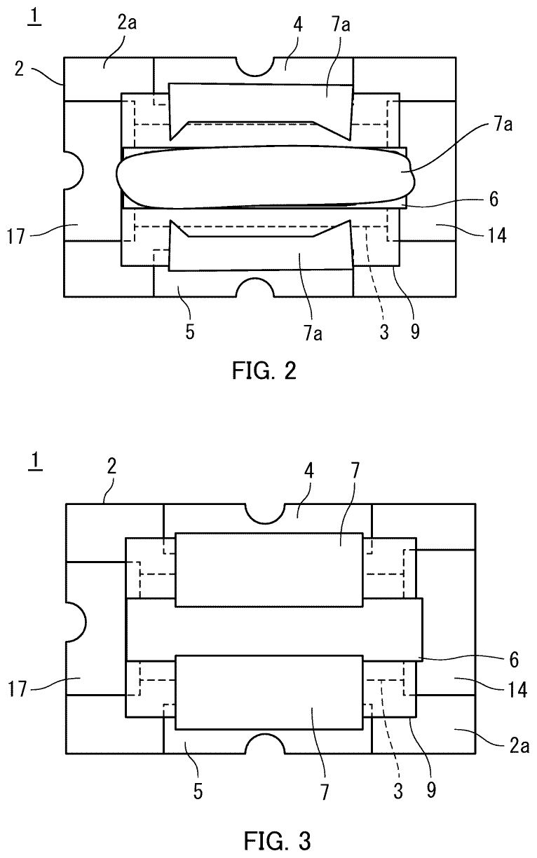

When the protecting device 1 is incorporated into an external circuit, the fuse element 7 forms part of the current path of the external circuit and interrupts the current path by melting under predetermined conditions (see FIG. 2). The following sections describes the details of each component of the protecting device 1.

The protecting device 1 shown in FIGS. 1A to 1C is equipped with a heat generator 3, and the fuse element 7 is blown by the heat generated by the heat generator 3 or by an overcurrent exceeding the rated value. In other words, the protecting device 1 includes the insulating substrate 2, the heat generator 3 provided on the insulating substrate 2, the first electrode 4 and the second electrode 5 provided on the insulating substrate 2, a heat-generator lead-out electrode 6 disposed between the first electrode 4 and the second electrode 5 and electrically connected to one end of the heat generator 3, and the fuse element 7 disposed on surfaces of the first electrode 4, the second electrode 5 and the heat-generator lead-out electrode 6 to provide electrical connection between the first electrode 4 and heat-generator lead-out electrode 6 and between the second electrode 5 and heat-generator lead-out electrode 6.

### Insulating Substrate

The insulating substrate 2 is formed of an insulating materials such as alumina, glass ceramics, mullite, or zirconia. Alternatively, the insulating substrate 2 may be made of other materials used for printed wiring boards, such as glass epoxy and phenolic substrates. The insulating substrate 2 may be provided with glass or solder resist at predetermined positions for the purpose of insulation and position control of the connecting conductor 8 and the fuse element 7. In this specification, the surface of the insulating substrate 2 on which the fuse element 7 is mounted is referred to as the front surface 2a, and the opposite surface on which the fuse element 7 is mounted is referred to as the back surface 2b.

### First and Second Electrodes

On the front surface 2a of the insulating substrate 2 at the two ends opposing each other, the first electrode 4 and the second electrode 5 are formed. The first electrode 4 and the second electrode 5 are formed by a conductive pattern of Ag, Cu, or an alloy thereof. The first electrode 4 and the second electrode 5 can be formed by printing Ag paste in a predetermined pattern by screen printing and then baking at a predetermined temperature.

The first electrode 4 is connected to the first external connection electrode 11 formed on the back surface 2b of the insulating substrate 2 via castellation from the front surface 2a of the insulating substrate 2. The second electrode 5 is connected to the second external connection electrode 12 formed on the back surface 2b of the insulating substrate 2 via castellation from the front surface 2a of the insulating substrate 2. When the protecting device 1 is mounted on the external circuit board, the first and second external connection electrodes 11 and 12 are connected to the connection electrodes provided on the external circuit board, thereby incorporating the fuse element 7 into part of the current path formed on the external circuit board.

The first and second electrodes 4, 5 are electrically connected via the fuse element 7 by the fuse element 7 being mounted via the connecting conductor 8. As shown in FIG. 2, the first and second electrodes 4, 5 are disconnected by the heat generator 3 generating heat when energized, causing the fuse element 7 to melt, or by the protecting device 1 being subjected to a large current exceeding its rated current, causing the fuse element 7 to melt due to self-heating (Joule heat).

### Heat-Generator Lead-Out Electrode

The heat-generator lead-out electrode 6 is provided in the area between the first electrode 4 and the second electrode 5, and one end of the heat-generator lead-out electrode 6 is connected to the intermediate electrode 14 described below. The heat-generator lead-out electrode 6 is stacked on the insulating protective layer 9 to be described later, and overlaps the heat generator 3 via the insulating protective layer 9.

As with the first and second electrodes 4, 5, the heat-generator lead-out electrode 6 can be formed by printing and baking conductive paste such as Ag or Cu. Between the first and second electrodes 4, 5, the fuse element 7 is connected to the heat-generator lead-out electrode 6 via the connecting conductor 8.

### Connecting Conductor

The connecting conductor 8 connects the first and second electrodes 4, 5 and the heat-generator lead-out electrode 6 to the fuse element 7, and is formed by a paste solder alloy or the like. Specifically, the connecting conductor 8 is a metal bonding material having a liquidus point lower than that of the fuse element 7 and a solidus point lower than the reflow heating temperature (260° C.), for example, a tin-based alloy or an indium-based alloy. Among these, Sn—Ag3-Cu0.5 (solidus point: 217° C./liquidus point: 220° C.), Sn—Ag 3.5 (solidus point: 221° C./liquidus point: 223° C.), Sn—Cu solder, or Sn—Sb—Ag—Cu solder is suitable. In particular, the inclusion of Sb makes it easy to adjust the liquidus and solidus points to a desired range.

The connecting conductor 8 is supplied to the position where the fuse element 7 is to be mounted on the first and second electrodes 4, 5 and the heat-generator lead-out electrode 6 by screen printing or other known methods and is subjected to a reflow process after the fuse element 7 is mounted. Since the connecting conductor 8 is a material having a liquidus point lower than the liquidus point of the fuse element 7 and a solidus point lower than the reflow heating temperature, it is provided for connection between the fuse element 7 and the first and second electrodes 4, 5 in an at least partially melting state, preferably in a completely melted state at the reflow heating temperature. This allows the connecting conductor 8 to wetly spread over the first and second electrodes 4, 5 as well as to fill the space between the fuse element 7 and the first and second electrodes 4, 5 to electrically and mechanically connect them.

It is preferable that a coating such as Ni/Au plating, Ni/Pd plating, or Ni/Pd/Au plating is applied to the surfaces of the first and second electrodes 4, 5 and the heat-generator lead-out electrode 6 using a known method such as plating. This allows the protecting device 1 to prevent the oxidation of the first and second electrodes 4, 5 and the heat-generator lead-out electrode 6 and to prevent fluctuations in ratings due to increased conduction resistance. In addition, when the protecting device 1 is reflow mounted, the coating will prevent the first and second electrodes 4, 5 and the heat-generator lead-out electrode 6 from being eroded by the melted connecting conductor 8 (solder erosion) used to connect the fuse element 7.

In addition, the first and second electrodes 4, 5 may be provided with a regulatory wall to prevent the connecting solder provided on the electrodes of the external circuit board to be connected to the first and second external connection electrodes 11, 12 and melted during reflow mounting or the like from crawling up onto the first and second electrodes 4, 5 via the castellation and wetly spreading over the first and second electrodes 4, 5. The regulatory wall can be formed using an insulating materials that does not have wettability for solder, such as glass, solder resist, or insulating adhesives, and can be formed on the first and second electrodes 4, 5 by printing or other means. The regulatory wall prevents the melted connecting solder from wetly spreading to the first and second electrodes 4, 5, thereby maintaining the connectivity between the protecting device 1 and the external circuit board.

### Heat Generator

As shown in FIG. 1A, the heat generator 3 is formed on the front surface 2a of the insulating substrate 2. The heat generator 3 is an electrically conductive member having a relatively high resistance value and generating heat when energized, and is made of, e.g., nichrome, W, Mo, Ru, or a material containing these materials. The heat generator 3 can be formed by mixing the powder of these alloys, compositions, or compounds with a resin binder or the like to form a paste, forming a pattern on the insulating substrate 2 using screen printing technology, and then baking the paste. As an example, the heat generator 3 can be formed by preparing a mixture of ruthenium oxide paste and silver/glass paste according to a predetermined voltage, applying the mixture to form a film with a predetermined area at a predetermined position on the front surface 2a of the insulating substrate 2, and then baking the mixture under appropriate conditions. The shape of heat generator 3 can be designed as needed, but as shown in FIG. 1A, it is preferable to make it substantially rectangular in shape according to the shape of the insulating substrate 2 in order to maximize the heating area.

The heat generator 3 is connected to the heat-generator electrode 17 at one end 3a and to the intermediate electrode 14 at the other end 3b. The heat-generator electrode 17 and the intermediate electrode 14 are formed on opposite side edges of the insulating substrate 2 different from the side edges provided with the first and second electrodes 4, 5. The heat-generator electrode 17, which is a power supply electrode to the heat generator 3, is connected to one end 3a of the heat generator 3 and is also connected to the third external connection electrode 13 formed on the back surface 2b of the insulating substrate 2 via castellation.

The intermediate electrode 14 is provided between the heat generator 3 and the heat-generator lead-out electrode 6 stacked on the insulating protective layer 9 and is connected to the other end 3b of the heat generator 3 as well as to the heat-generator lead-out electrode 6.

As with the first and second electrodes 4, 5, the heat-generator electrode 17 and the intermediate electrode 14 can be formed by printing and baking conductive paste such as Ag, Cu, or an alloy of these. In addition, by using the same material, each of these electrodes can be formed on the front surface 2a of the insulating substrate 2 in a single printing and baking process.

### Insulating Protective Layer

The heat generator 3 is covered with an insulating protective layer 9. The insulating protective layer 9 is provided to protect and insulate the heat generator 3 and to efficiently transfer the heat of the heat generator 3 to the heat-generator lead-out electrode 6 and the fuse element 7 and is made of an insulating material such as glass that has heat resistance to the heating temperature of the heat generator 3. Examples of glass materials that can be used to make the insulating material 9 include silica glass overcoat glass paste and insulating glass paste.

The insulating protective layer 9 can be formed by applying these glass pastes using screen printing or other methods and baking the paste. In the protecting device 1 shown in FIGS. 1A and 1B, the insulating protective layer 9 is formed to cover the heat generator 3 formed on the front surface 2a of the insulating substrate 2.

The thickness of the insulating protective layer 9 is set appropriately in accordance with the coating properties of the glass paste or the like and the required interruption time of the fuse element 7, and is set to be, e.g., 10 μm or more and 40 μm or less, and preferably 20 μm or more and 40 μm or less.

### Fuse Element

Next, the fuse element 7 will be explained. The fuse element 7 is mounted between the first and second electrodes 4, 5 and melts due to heat generation caused by the heat generator 3 being energized or self-heating (Joule heat) caused by the current exceeding its rated value flowing therethrough, thereby interrupting the current path between the first electrode 4 and the second electrode 5. The fuse element 7 is connected to the first and second electrodes 4, 5 and the heat-generator lead-out electrode 6 via the connecting conductor 8.

The fuse element 7 is formed of a conductive material that melts due to the heat generated by the energized heat generator 3 or by an overcurrent condition. As mentioned above, the fuse element 7 is made of an alloy having a material composition which does not contain lead and has a liquidus point higher than the reflow heating temperature (260° C.). In other words, the fuse element 7 does not melt at the reflow heating temperature. Therefore, since the fuse element 7 does not melt during the reflow process, the fuse element 7 can be connected to the first and second electrodes 4, 5 and the heat-generator lead-out electrode 6, and the protecting device 1 can be mounted on the external circuit board efficiently by reflow.

In a structure in which a high-melting-point metal covers a low-melting-point metal with liquidus point lower than the reflow temperature, the low-melting-point metal covered by the high-melting-point metal layer will flow and deform during the reflow process and the deformation will affect the rapid blowout property; on the other hand, the fuse element 7 formed of an alloy with a material composition with a liquidus point higher than the reflow heating temperature (260° C.) does not have these problems.

The material of fuse element 7 may be a tin-based alloy such as Sn—Cu solder or Sn—Sb—Ag—Cu solder, and specifically, Sn—Sb10 (solidus point: 246° C., liquidus point: 272° C.), Sn—Cu7.0 (solidus point: 227° C., liquidus point: about 400° C.), Sn—Sb35-Cu5-Ag5 (solidus point: 300° C., liquidus point: about 350° C.) can be suitably used. In particular, the inclusion of Sb makes it easy to adjust the liquidus and solidus points to a desired range.

The fuse element 7 preferably has a liquidus temperature of 400° C. or less. If the liquidus temperature exceeds 400° C., the time required for melting may be extended and the heat generator 3 may be damaged before the fuse element 7 melts.

The fuse element 7 can take any shape, but from the viewpoint of downsizing and improving rating, it is preferably formed in the shape of a rectangular plate as shown in FIG. 1A. The protecting device 1 may have one fuse element 7 mounted from the first electrode 4 to the second electrode 5 or may have fuse elements 7 mounted between the first electrode 4 and the heat-generator lead-out electrode 6 and between the heat-generator lead-out electrode 6 and the second electrode 5, respectively, as shown in FIG. 3. Furthermore, protecting device 1 may have a plurality of fuse elements 7 in parallel from the first electrode 4 to the second electrode 5 or may have a plurality of fuse elements 7 in parallel between the first electrode 4 and the heat-generator lead-out electrode 6 and between the heat-generator lead-out electrode 6 and the second electrode 5, respectively.

The fuse elements 7 does not melt due to self-heating as long as the predetermined rated current flows. When a current exceeding the rated value flows, the fuse element 7 melts due to self-heating and interrupts the current path between the first and second electrodes 4, 5. In addition, the fuse element 7 melts when the heat generator 3 is energized to generate heat and the melted conductor agglomerates on the first and second electrodes 4, 5 and the heat-generator lead-out electrode 6 by the drawing action to be blown between each electrode, thereby interrupting the current path between the first and second electrodes 4, 5.

The fuse element 7 may be coated with flux to prevent oxidation and to improve wettability at the time of blowout. In the protecting device 1, the insulating substrate 2 is protected by being covered by the case 30. The case 30 can be formed from an insulating material such as various engineering plastics, thermoplastics, ceramics, and glass epoxy substrates, among others. The case 30 has a sufficient internal space on the front surface 2a of the insulating substrate 2 for the fuse element 7 to expand spherically when melted and for the melted conductor 7a to agglomerate on the heat-generator lead-out electrode 6 and the first and second electrodes 4, 5.

### Circuit Configuration Example

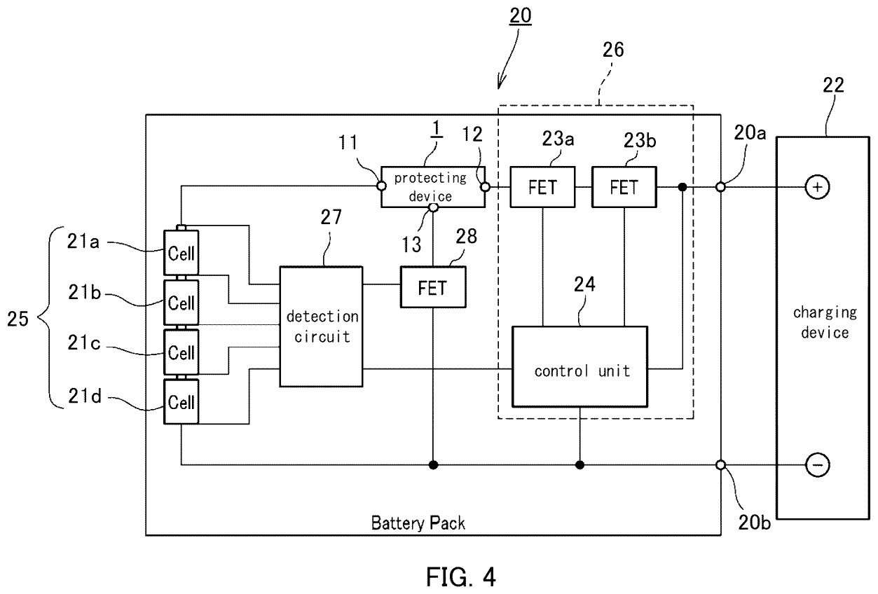

Next, a circuit configuration example of a lithium-ion secondary battery that employs the protecting device 1 will be described. The technology is not limited to the following configuration. The protecting device 1 is used, e.g., in the circuit in a battery pack 20 of a lithium-ion secondary battery. The battery pack 20 includes a battery stack 25 having a plurality of, e.g., a total of four lithium-ion secondary battery cells 21a to 21d, as shown in FIG. 4.

The battery pack 20 includes a battery stack 25, a charge/discharge control circuit 26 that controls the charge/discharge of the battery stack 25, the protecting device 1 according to the present invention that interrupts a charging/discharging path when the state of the battery stack 25 is abnormal, a detection circuit 27 that detects the voltage of each battery cell 21a to 21d, and a current control element 28 that serves as a switch element to control the operation of the protecting device 1 in accordance with the detection results of the detection circuit 27.

In the battery stack 25, the battery cells 21a to 21d requiring control for protection from over-charging and over-discharging states are connected in series and are detachably connected to the charging device 22 via a positive electrode terminal 20a and a negative electrode terminal 20b of the battery pack 20, so as to apply charging voltage from the charging device 22. By connecting the positive electrode terminal 20a and the negative electrode terminal 20b to a battery-driven electronic device, the battery pack 20 charged by the charging device 22 can drive the electronic device.

The charge/discharge control circuit 26 includes two current control elements 23a, 23b connected in series in the current path between the battery stack 25 and the charging device 22, and a control unit 24 for controlling operations of the current control elements 23a, 23b. The current control elements 23a, 23b are formed of, for example, a field effect transistors (hereinafter referred to as FETs) and the control unit 24 controls the gate voltage to switch the current path of the battery stack 25 between a conducting state and an interrupted state in the charging and/or discharging direction. The control unit 24 is powered by the charging device 22 and controls the operation of the current control elements 23a, 23b in accordance with the detection result by the detection circuit 27 to interrupt the current path when over-discharging or over-charging occurs in the battery stack 25.

The protecting device 1 is connected in a charge/discharge current path between the battery stack 25 and the charge/discharge control circuit 26, for example, and the operation thereof is controlled by the current control element 28.

The detection circuit 27 is connected to each of the battery cells 21a to 21d so as to detect the voltage values of each of the battery cells 21a to 21d and supplies each of the voltage values to the control unit 24 of the charge/discharge control circuit 26. Furthermore, when an over-charging voltage or an over-discharging voltage is detected in any one of the battery cells 21a to 21d, the detection circuit 27 outputs a control signal for controlling the current control element 28.

When the detection signal output from the detection circuit 27 indicates a voltage exceeding a predetermined threshold value corresponding to over-discharging or over-charging state of the battery cells 21a to 21d, the current control element 28 such as an FET, for example, activates the protecting device 1 to interrupt the charging/discharging current path of the battery stack 25 without the switching operation of the current control elements 23a, 23b.

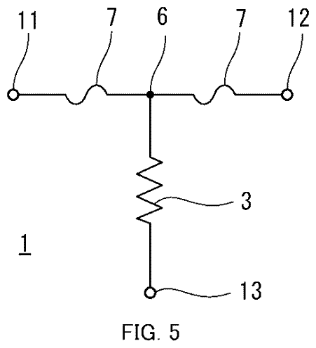

The protecting device 1 according to the present technology, which is used in the battery pack 20 having the above-described configuration, has a circuit configuration as shown in FIG. 5. That is, in the protecting device 1, the first external connection electrode 11 is connected to the battery stack 25 side, and the second external connection electrode 12 is connected to the positive electrode terminal 20a side, whereby the fuse element 7 is connected in series in the charging/discharging path of the battery stack 25. Furthermore, in the protecting device 1, the heat generator 3 is connected to the current control element 28 via the heat-generator electrode 17 and the third external connection electrode 13, and the heat generator 3 is also connected to the battery stack 25. In this way, one end of the heat generator 3 is connected to the fuse element 7 and one end of the battery stack 25 via the heat-generator lead-out electrode 6, and the other end of the heat generator 3 is connected to the current control element 28 and the other end of the battery stack 25 via the heat-generator electrode 17 and the third external connection electrode 13. This forms a power supply path to the heat generator 3 the conduction of which is controlled by the current control element 28.

### Operation of Protecting Device

Upon detecting an abnormal voltage in any of the battery cells 21a to 21d, the detection circuit 27 outputs an interruption signal to the current control element 28. The current control element 28 then controls the current so as to energize the heat generator 3. In the protecting device 1, electrical current flows from the battery stack 25 to the heat generator 3, and this causes the heat generator 3 to start generating heat. The protecting device 1 causes the fuse element 7 to melt due to the heat generated by the heat generator 3 to interrupt the charging/discharging path of the battery stack 25.

The melted conductor 7a of the fuse element 7 aggregate on the connection portions 8 formed on the first electrode 4, the second electrode 5, and the heat-generator lead-out electrode 6, thereby interrupting the current path between each electrode (FIG. 2). At this time, positive tension is exerted on the melted conductor 7a to aggregate on the first electrode 4, the second electrode 5, and the heat-generator lead-out electrode 6, so that the connection between the first electrode 4 and heat-generator lead-out electrode 6 and the connection between the second electrode 5 and heat-generator lead-out electrode 6 can be interrupted more quickly.

Unlike a structure in which a high-melting-point metal covers a low-melting-point metal with liquidus point lower than the reflow temperature, the fuse element 7, which is made of an alloy having a material composition with a liquidus temperature is higher than the reflow heating temperature (260° C.), can melt within a predetermined time and interrupting the current path without any effect on the rapid blowout property due to deformation of the fuse element 7 by reflow. This ability to quickly melt the fuse element 7 also prevents the heat generator 3 from being damaged before the fuse element 7 melts, allowing the current path to be safely and quickly interrupted.

The protecting device 1 stops the heating of the heat generator 3 by blowing the fuse element 7 to interrupt the power supply path to the heat generator 3.

In addition, when a rate-exceeding overcurrent flows through the battery pack 20, the protecting device 1 can blow the fuse element 7 by self-heating to interrupt the charging/discharging path of the battery pack 20.

The protecting device 1 according to the present technology is not limited to the cases where it is used for a battery pack of a lithium-ion secondary battery, and is of course applicable to various applications requiring interruption of a current path by an electric signal.

### Modification 1

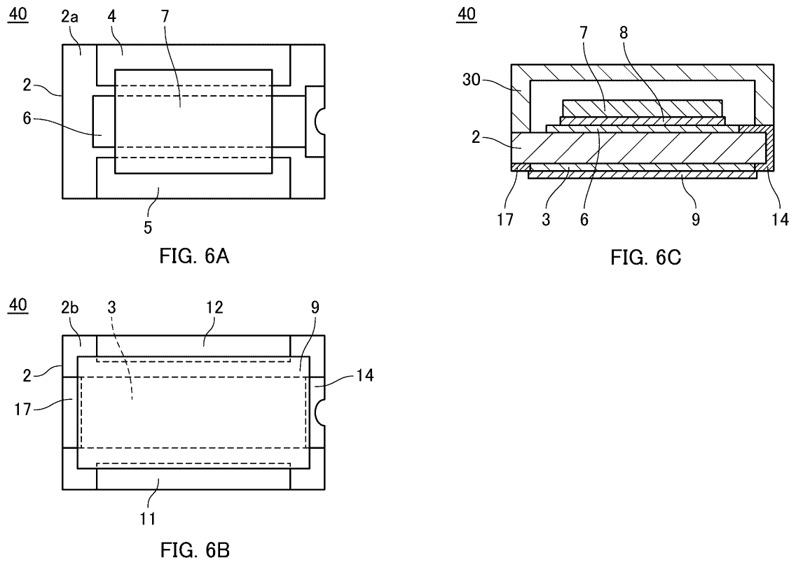

Next, a modification of the protecting device according to the present technology is described. In the following description, the same parts and materials as those of the above-described protecting device 1 are indicated with the same symbols and their details may be omitted. The protecting device 40 shown in FIGS. 6A to 6C is formed by forming the heat generator 3, the heat-generator electrode 17, the intermediate electrode 14, and the insulating protective layer 9 on the back surface 2b of the insulating substrate 2, and the other configuration is the same as the protecting device 1 described above.

The heat-generator electrode 17 and the intermediate electrode 14 are formed on opposite side edges of the back surface 2b of the insulating substrate 2 different from the side edges provided with the first and second electrodes 4, 5. The heat-generator electrode 17 serves as a feeding electrode to the heat generator 3 as well as an external connection electrode, and is connected to the current control element 28 when the protecting device 40 is mounted on an external circuit.

The intermediate electrode 14 is provided between the heat generator 3 and the heat-generator lead-out electrode 6 provided on the front surface 2a of the insulating substrate 2 and is connected to the other end 3b of the heat generator 3, as well as being connected to the heat-generator lead-out electrode 6 formed on the front surface 2a of the insulating substrate 2 via castellation.

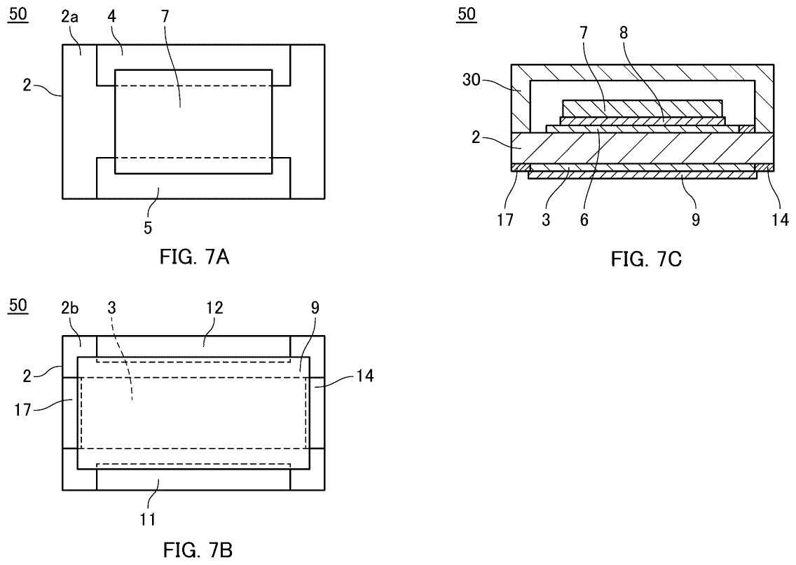

As shown in FIG. 7B, the protecting device may have the heat generator 3 formed on the back surface 2b of the insulating substrate 2 and may also have the power supply path to the heat generator 3 and the current path of the fuse element 7 formed independently. The protecting device 50 shown in FIG. 7A omits the heat-generator lead-out electrode 6, but may be provided with the heat-generator lead-out electrode 6 that is not connected to the intermediate electrode 14. By omitting the heat-generator lead-out electrode 6, the protecting device 50 separates the current path of the fuse element 7 and the current path of the heat generator 3. The heat generator 3 formed on the back surface 2b of the insulating substrate 2 is connected to the heat-generator electrode 17 at one end and to the intermediate electrode 14 at the other end.

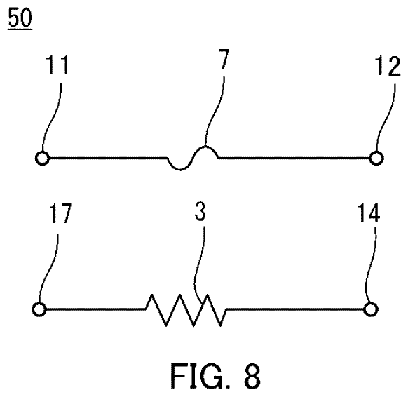

FIG. 8 shows the circuit configuration of the protecting device 50. When the protecting device 50 is mounted on the external circuit, the first external connection electrode 11 is connected to the battery stack 25 side, and the second external connection electrode 12 is connected to the positive electrode terminal 20a side, whereby the fuse element 7 is connected in series on the charging/discharging path of the battery stack 25. The heat generator 3 is connected to the current control element 28 via the heat-generator electrode 17 and is also connected to the battery stack 25. In addition, the heat generator 3 is connected to ground (not shown) via the intermediate electrode 14. This forms a power supply path to the heat generator 3 the conduction of which is controlled by the current control element 28. In the protecting device 50, when the fuse element 7 melts, the detection circuit 27 and the current control element 28 detect this and stop the power supply to the heat generator 3.

### Modification 2

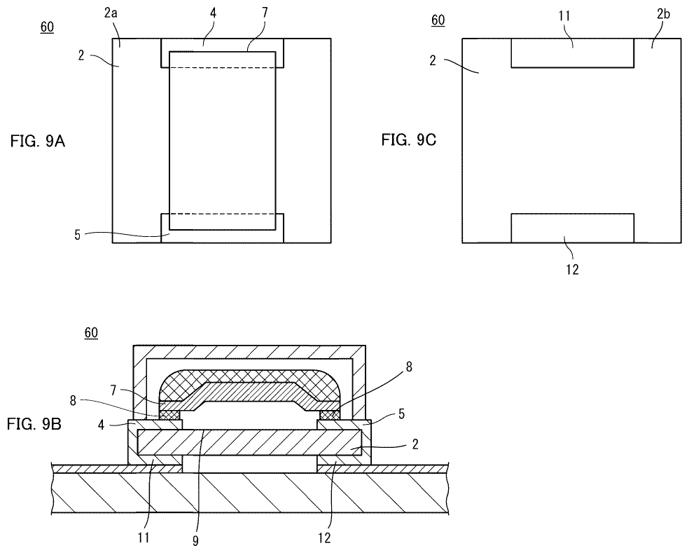

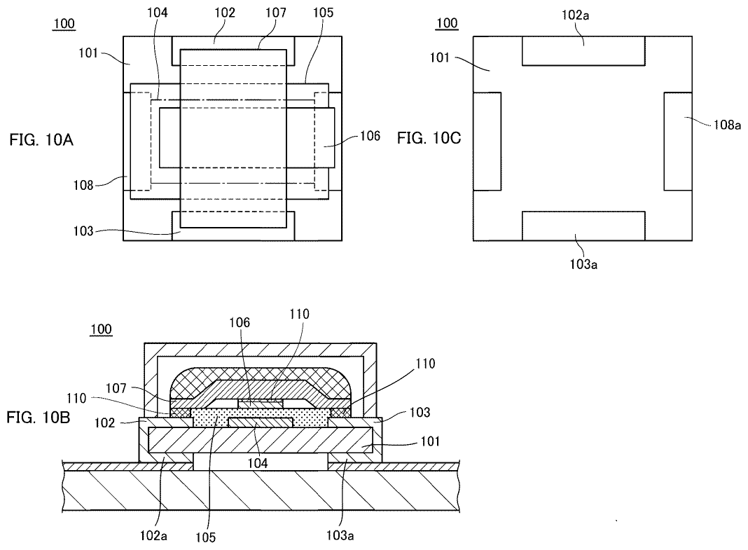

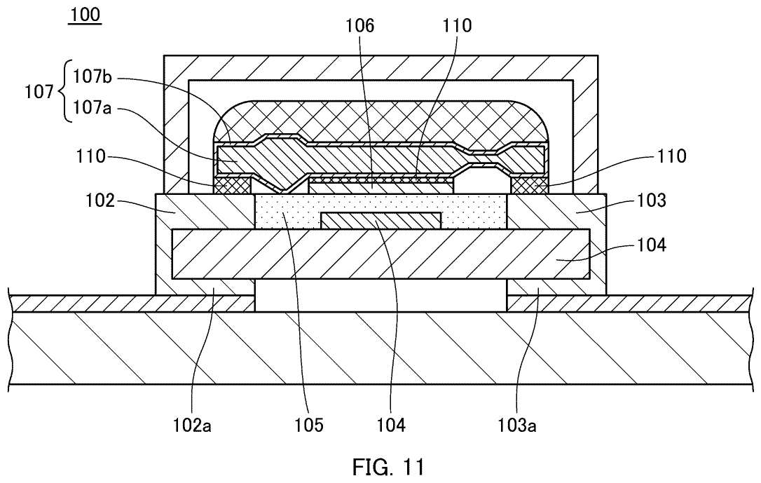

Next, another modification of the protecting device according to the present technology is described. In the following description, the same parts and materials as those of the above-described protecting devices 1, 40, and 50 are indicated with the same symbols and their details may be omitted. As shown in FIGS. 9A to 9C, the protecting device 60 according to the present technology interrupts the current path by self-heating of the fuse element 7 due to overcurrent without being provided with the heat generator 3.

The protecting device 60 is reflow-mounted on an external circuit board, whereby the first external connection electrode 11 is connected to the battery stack 25 side and the second external connection electrode 12 is connected to the positive electrode terminal 20a side, so that the fuse element 7 is connected in series in the charging/discharging path of the battery stack 25.

In the protecting devices 40, 50, 60 described above as well, since the connecting conductor 8 is a material having a liquidus point lower than the liquidus point of the fuse element 7 and a solidus point lower than the reflow heating temperature, it is provided for connection between the fuse element 7 and the first and second electrodes 4, 5 in an at least partially melting state, preferably in a completely melted state at the reflow heating temperature. This allows the connecting conductor 8 to wetly spread over the first and second electrodes 4, 5 and the heat-generator lead-out electrode 6, as well as to fill the space between the fuse element 7 and the first and second electrodes 4, 5 and the heat-generator lead-out electrode 6 to electrically and mechanically connect them.

In addition, by using as the fuse element 7 an alloy having a material composition which does not use lead and has a liquidus point higher than the reflow heating temperature, the protecting devices 40, 50, 60 have an excellent rapid blowout property while reducing the environmental burden. In addition, it is possible to reduce the environmental impact while maintaining the rapid blowout property without using expensive metals such as gold as the fuse element 7, thus reducing the cost.

### REFERENCE SIGNS LIST

1 protecting device, 2 insulating substrate, 3 heat generator, 4 first electrode, 5 second electrode, 6 heat-generator lead-out electrode, 7 fuse element, 8 connecting conductor, 9 insulating protective layer, 11 first external connection electrode, 12 second external connection electrode, 13 third external connection electrode, 14 intermediate electrode, 17 heat-generator electrode, 20 battery pack, 21 battery cell, 22 charging device, 23 current control element, 24 control unit, 25 battery stack, 26 charge/discharge control circuit, 27 detection circuit, 28 current control element, 30 case, 40 protecting device, 50 protecting device, 60 protecting device

1. A protecting device, comprising:
an insulating substrate;
a first electrode and a second electrode provided on the insulating substrate;
a fuse element disposed on a surface of the first electrode and the second electrode to electrically connect the first electrode and the second electrode; and
a connecting conductor that connects the first and second electrodes to the fuse element, wherein
the fuse element is made of a lead-free conductor and has a liquidus point higher than the reflow heating temperature, and
the connecting conductor has a liquidus point lower than the liquidus point of the fuse element and has a solidus point lower than the reflow heating temperature.

2. The protecting device according to claim 1, wherein the fuse element has a liquidus temperature of 400° C. or less.

3. The protecting device according to claim 2, wherein the fuse element is a Sn—Cu, or Sn—Sb—Ag—Cu alloy.

4. The protecting device according to claim 1, wherein the connecting conductor is a Sn—Cu—Ag, Sn—Cu, or Sn—Sb—Ag—Cu solder alloy.

5. The protecting device according to claim 1, further comprising:
a heat generator provided on the insulating substrate;
a heat-generator electrode connected to one end of the heat generator;
an intermediate electrode connected to the other end of the heat generator;
an insulating protective layer covering at least the heat generator; and
a heat-generator lead-out electrode provided between the first electrode and the second electrode and connected to the intermediate electrode.

6. The protecting device according to claim 1, further comprising an external connection electrode to be connected to a terminal provided on an external circuit board, thereby being surface mountable on the external circuit board.
